(19) United States
(12) Patent Application Publication
(10) Pub. No.: US 2024/0412941 A1
(43) Pub. Date: Dec. 12, 2024

(54) Lamella Mounting Method, and Analysis System

(71) Applicant: Hitachi High-Tech Corporation, Minato-ku, Tokyo (JP)

(72) Inventors: Wei Chean TAN, Tokyo (JP); Shinsuke KAWANISHI, Tokyo (JP); Tsunenori NOMAGUCHI, Tokyo (JP); Hiroyuki CHIBA, Tokyo (JP)

(21) Appl. No.: 18/274,047

(22) PCT Filed: Jan. 29, 2021
(86) PCT No.: PCT/JP2021/003203

§ 371 Date: Jul. 25, 2023

(51) Int. Cl. H01J 37/20; H01J 37/26

(52) U.S. Cl. CPC H01J 37/20; H01J 37/26

(57) ABSTRACT

A lamella mounting method that can achieve improvement in transport throughput is provided. Provided is a lamella mounting method including (a) a step of gripping a lamella 10 fabricated on a part of a wafer 1 and taking out the lamella 10 from the wafer 1 by nano-tweezers 62, and (b) a step of bringing the lamella 10 into close contact with a film 22 contained in a mesh 20 by moving the nano-tweezers 62 to press the lamella 10 against the film 22 while the lamella 10 is being gripped by the nano-tweezers 62, in which, after the step (b), the lamella 10 is in close contact with the film 22 so that an analysis region 11 faces the film 22.

### TECHNICAL FIELD

The present invention relates to a lamella mounting method and an analysis system, and more particularly to a mounting method for mounting a lamella to be analyzed using a charged particle beam device onto a mesh by tweezers, and an analysis system to which the mounting method is applied.

### BACKGROUND ART

In the field of semiconductor devices, improvements in performance have been achieved through miniaturization. In recent years, the use of new materials to replace silicon such as compound semiconductors, the promotion of three-dimensional structures, and techniques for improving device performance by methods other than miniaturization are attracting attention. In such new efforts, the importance of techniques for analyzing an interfacial state and lamination structure between different materials is increasing.

For example, a method, in which a lamella (thin piece sample) is fabricated by a lamella fabrication device such as a focused ion beam (FIB) device from a part of a wafer made of semiconductor or the like, the lamella is mounted on a lamella carrier by a lamella mounting device, and the lamella on the lamella carrier is analyzed by a lamella analysis device (charged particle beam device), is performed. The charged particle beam device is, for example, a scanning electron microscope (SEM), a transmission electron microscope (TEM), or a scanning transmission electron microscope (STEM).

Usually, the fabricated lamella is mounted on the lamella carrier or the like, and the lamella carrier on which the lamella is mounted is transported to the charged particle beam device. For example, PTL 1 discloses a method of fixing a lamella to a sample holder by preparing the sample holder having a recessed fitting part and fitting the lamella fabricated from a part of a semiconductor wafer into the recessed fitting part by a charged particle beam. PTL 2 discloses a technique of fabricating a lamella from a part of the semiconductor wafer using the charged particle beam and mounting the lamella on the sample holder while gripping the lamella by tweezers.

### CITATION LIST

### Patent Literature

PTL 1: JP2009-115582A
PTL 2: JP2009-133833A

### SUMMARY OF INVENTION

### Technical Problem

It is desired to evaluate the quality of a wafer by automatically performing a series of flows for acquiring interface information and a lamination structure within the wafer. For example, if it is possible to construct an analysis system in which multiple lamellae are fabricated from one wafer, the multiple lamellae are collectively mounted on one lamella carrier, and the multiple lamellae are sequentially analyzed with the charged particle beam device, the throughput of quality evaluation of the wafer can be improved.

As a general example of mounting the lamella, the lamella gripped by tweezers is mounted on a half-moon type lamella carrier. However, in the half-moon type lamella carrier, the number of lamellae mounted is smaller than that of a mesh represented by a full moon type, for example. Therefore, it is necessary to frequently replace the lamella carrier during lamella analysis.

If the lamellae can be mounted using tweezers on the mesh that can mount more lamellae than the half-moon type lamella carrier, transport throughput can be improved.

One of the objects of the present application is to provide a lamella mounting method capable of improving the transport throughput. An analysis system capable of improving the throughput of quality evaluation of the wafer by applying the mounting method thereto is provided. Other problems and novel features will become apparent from the description of the specification and the accompanying drawings.

### Solution to Problem

A brief outline of representative embodiments among the embodiments disclosed in the present application is as follows.

A lamella mounting method according to one embodiment is a method for mounting a lamella to be analyzed using a charged particle beam device on a mesh by tweezers. The lamella mounting method includes (a) a step of gripping the lamella fabricated on a part of a wafer and taking out the lamella from the wafer by the tweezers and (b) after the step (a), a step of bringing the lamella into close contact with a first film contained in a mesh by moving the tweezers to press the lamella against the first film while the lamella is being gripped by the tweezers. Here, the lamella includes a body and an analysis region provided in a part of the body, a width of the analysis region in a first direction is different from a width of the body in the first direction, and, after the step (b), the lamella is in close contact with the first film so that the analysis region faces the first film.

An analysis system according to one embodiment includes lamella fabrication device that includes an ion beam column, a lamella mounting device that includes tweezers for gripping a lamella and a mesh for mounting the lamella, and a lamella analysis device that includes an electron beam column including an electron source, a sample stage, and a holder provided on the sample stage. The analysis system includes (a) in the lamella fabrication device, a step of fabricating the lamella including a body and an analysis region provided in a part of the body by irradiating a wafer with an ion beam from the ion beam column and etching a part of the wafer, (b) after the step (a), a step of transporting the wafer on which the lamella is fabricated from the lamella fabrication device to the lamella mounting device, (c) after the step (b), in the lamella mounting device, a step of gripping the lamella fabricated on a part of the wafer and taking out the lamella from the wafer by the tweezers, (d) after the step (c), in the lamella mounting device, a step of bringing the lamella into close contact with a first film contained in a mesh by moving the tweezers to press the lamella against the first film while the lamella is being gripped by the tweezers, (e) after the step (d), a step of transporting the mesh on which the lamella is mounted from the lamella mounting device to the lamella analysis device, and (f) after the step (e), in the lamella analysis device, a step of analyzing the analysis region by irradiating the analysis region with an electron beam from the electron source while the mesh is being placed on the holder so that the analysis region faces the electron source. Here, a width of the analysis region in a first direction is different from a width of the body in the first direction, and, after the step (d) and before the step (e), the lamella is in close contact with the first film so that the analysis region faces the first film.

### Advantageous Effects of Invention

According to one embodiment, it is possible to provide a lamella mounting method capable of improving transport throughput. It is possible to provide an analysis system capable of improving throughput of quality evaluation of the wafer by applying the mounting method thereto.

### BRIEF DESCRIPTION OF DRAWINGS

FIG. 1 is a schematic diagram illustrating an analysis system according to Embodiment 1.

FIG. 2 is a schematic diagram illustrating a lamella fabrication device according to Embodiment 1.

FIG. 3 is a schematic diagram illustrating a lamella mounting device according to Embodiment 1.

FIG. 4 is a schematic diagram illustrating a lamella analysis device according to Embodiment 1.

FIG. 5 is a schematic diagram illustrating an example of the lamella analysis device according to Embodiment 1.

FIG. 6 is a schematic diagram illustrating another example of the lamella analysis device according to Embodiment 1.

FIG. 7 is a perspective view illustrating a wafer and a lamella according to Embodiment 1.

FIG. 8 is a perspective view illustrating a lamella taking-out method according to Embodiment 1.

FIG. 9 is a plan view illustrating a mesh according to Embodiment 1.

FIG. 10 is a processing flow diagram of the analysis system according to Embodiment 1.

FIG. 11 is a processing flow diagram of a lamella mounting method according to Embodiments 1 and 2.

FIG. 12 is a side view illustrating the lamella mounting method according to Embodiment 1.

FIG. 13 is a side view illustrating the lamella mounting method continued from FIG. 12.

FIG. 14 is a perspective view illustrating a lamella in Embodiment 2.

FIG. 15 is a side view illustrating the lamella mounting method according to Embodiment 2.

FIG. 16 is a side view illustrating the lamella mounting method continued from FIG. 15.

FIG. 17 is a processing flow diagram of a lamella mounting method according to Embodiments 3 and 4.

FIG. 18 is a side view illustrating the lamella mounting method according to Embodiment 3.

FIG. 19 is a side view illustrating the lamella mounting method continued from FIG. 18.

FIG. 20 is a perspective view illustrating a lamella according to Embodiment 4.

FIG. 21 is a side view illustrating the lamella mounting method according to Embodiment 4.

FIG. 22 is a side view illustrating the lamella mounting method continued from FIG. 21.

FIG. 23 is a plan view illustrating a mesh according to Embodiment 5.

FIG. 24 is a side view illustrating the mesh according to Embodiment 5.

FIG. 25 is a processing flow diagram of a lamella mounting method according to Embodiments 5 and 6.

FIG. 26 is a plan view illustrating the lamella mounting method continued from FIG. 25.

FIG. 27 is a plan view illustrating a mesh according to Embodiment 6.

FIG. 28 is a side view illustrating the mesh according to Embodiment 6.

FIG. 29 is a side view illustrating the lamella mounting method according to Embodiment 6.

### DESCRIPTION OF EMBODIMENTS

Hereinafter, embodiments will be described in detail based on the drawings. In all the drawings for describing the embodiments, members having the same functions are denoted by the same reference numerals, and repeated description thereof will be omitted. In the following embodiments, descriptions of the same or similar parts will not be repeated in principle unless particularly necessary.

The X-direction, Y-direction, and Z-direction described in the application intersect and are orthogonal to each other. In the application, the Z-direction may also be described as the vertical direction or height direction of a certain structure.

The main features of the application are a mounting method for mounting a lamella 10 on a mesh 20 by nano-tweezers 62 in a lamella mounting device 60, and an analysis system 30 to which the mounting method is applied. First, the analysis system 30 will be described, and then a detailed description of the mounting method of the lamella 10 will be made.

### Embodiment 1

### <Analysis System Configuration>

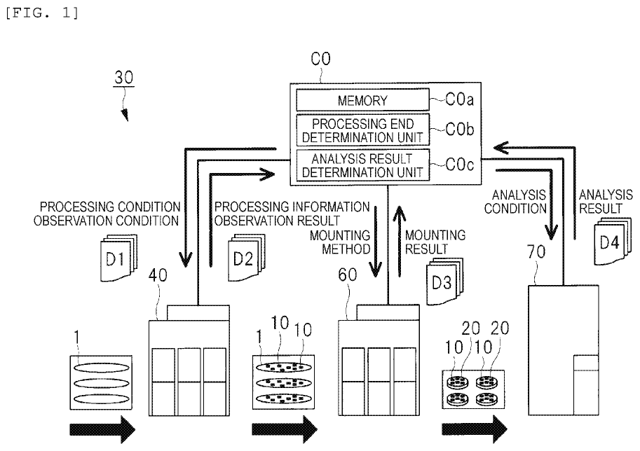

The analysis system 30 according to Embodiment 1 will be described below with reference to FIGS. 1 to 6.

As illustrated in FIG. 1, the analysis system 30 includes a lamella fabrication device 40, a lamella mounting device 60, a lamella analysis device 70, and a host control unit C0.

In the analysis system 30, a wafer 1 is transported from a semiconductor manufacturing line to the lamella fabrication device 40, and the lamella (thin piece sample) 10 is fabricated by etching a part of the wafer 1 in the lamella fabrication device 40. The wafer 1 including the fabricated lamella 10 is transported to the lamella mounting device 60 and mounted on a mesh (carrier) 20 in the lamella mounting device 60. After that, the mesh 20 on which the lamella 10 is mounted is transported to the lamella analysis device 70, and the lamella 10 is analyzed in the lamella analysis device 70.

In the transporting work performed between the lamella fabrication device 40, the lamella mounting device 60, and the lamella analysis device 70, the wafer 1 and the mesh 20 are stored inside a container (FOUP) filled with an inert gas such as nitrogen, and taken out from the container inside each device after the completion of transportation. The wafer 1 and the mesh 20 may be mounted in a cartridge that can be inserted into the lamella fabrication device 40 or the lamella analysis device 70. All or part of the handling of the wafer 1 or mesh 20 may be performed by a user or by a robot.

The lamella fabrication device 40, the lamella mounting device 60, the lamella analysis device 70, and the host control unit C0, which are the main components of the analysis system 30, will be described below.

### <Lamella Fabrication Device>

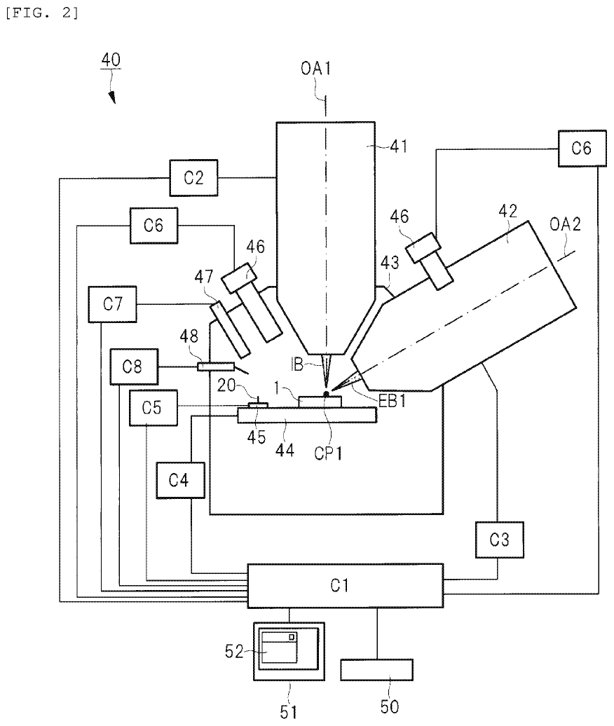

FIG. 2 is a schematic diagram illustrating the lamella fabrication device 40 according to Embodiment 1. The lamella fabrication device 40 is configured with a charged particle beam device such as an FIB-SEM device.

The lamella fabrication device 40 includes an ion beam column 41, an electron beam column 42, a sample chamber 43, a wafer stage 44, a sub-stage 45, a charged particle detector 46, an X-ray detector 47, a probe unit 48 and respective control units C1 to C8. An input device 50 and a display 51 are provided inside or outside the lamella fabrication device 40.

The ion beam column 41 includes all components necessary for an FIB device, such as an ion source for generating an ion beam (charged particle beam) IB, a lens for focusing the ion beam IB, and a deflection system for scanning and shifting the ion beam IB. Gallium ions are generally used as the ion beam IB, but ion species may be appropriately changed according to the purpose of processing and observation. The ion beam IB is not limited to a focused ion beam, and may be a broad ion beam with a mask.

The ion beam column control unit C2 controls the ion beam column 41. For example, generation of the ion beam IB from the ion source, driving of the deflection system, and the like are controlled by the ion beam column control unit C1.

The electron beam column 42 includes all the components necessary for an SEM device, such as an electron source for generating an electron beam (charged particle beam) EB1, a lens for focusing the electron beam EB1, and a deflection system for scanning and shifting the electron beam EB1.

The electron beam column control unit C3 controls the electron beam column 42. For example, generation of the electron beam EB1 from the electron source, driving of the deflection system, and the like are controlled by the electron beam column control unit C3.

The ion beam IB emitted from the ion beam column 41 and the electron beam EB1 emitted from the electron beam column 42 are mainly focused on a cross point CP1, which is the intersection of an optical axis OA1 of the ion beam column 41 and an optical axis OA2 of the electron beam column 42.

In Embodiment 1, the ion beam column 41 is disposed vertically and the electron beam column 42 is disposed tiltedly, but the disposition is not limited thereto, and the ion beam column 41 may be disposed tiltedly and the electron beam column 42 may be disposed vertically. Both the ion beam column 41 and the electron beam column 42 may be disposed tiltedly.

Instead of the ion beam column 41 and the electron beam column 42, a triple column with gallium focused ion beam column, argon focused ion beam column, and electron beam column may be configured.

The electron beam column 42 is provided for irradiating the wafer 1 with the electron beam EB1 and observing a structure of the wafer 1 at an irradiation position of the electron beam EB1. However, instead of the electron beam column 42, an observation system such as an optical microscope or an atomic force microscope (AFM) may be applied. A configuration in which the ion beam column 41 alone is used for both the processing and observation of the wafer 1 may be adopted.

The wafer stage 44 is provided in the sample chamber 43 at a position where the wafer 1 is irradiated with the ion beam IB and the electron beam EB1. The sub-stage 45 is provided on the wafer stage 44 on which the mesh 20 can be placed. Driving of the sub-stage 45 is controlled by the sub-stage control unit C5.

Driving of the wafer stage 44 is controlled by the wafer stage control unit C4. Therefore, the wafer stage 44 can perform planar movement, vertical movement, rotating movement, and tilting movement. By driving the wafer stage 44, the position and orientation of each of the wafer 1 and the sub-stage 45 can be freely changed. For example, the wafer stage 44 moves so that a desired location on the wafer 1 is positioned at the irradiation position of the ion beam IB or the irradiation position of the electron beam EB1.

The charged particle detector 46 detects charged particles generated when the wafer 1 or the lamella 10 is irradiated with the ion beam IB and the electron beam EB1. Here, the X-ray detector 47 detects X-rays generated from the wafer 1 or the lamella 10. The lamella fabrication device 40 may be provided with a composite charged particle detector capable of detecting not only electrons but also ions as the charged particle detector 46.

The detector control unit C6 can control the charged particle detector 46, and includes a circuit or an arithmetic processing unit that arithmetically processes a detection signal from the charged particle detector 46 and forms an image. The X-ray detector control unit C7 can control the X-ray detector 47, and includes an arithmetic processing unit for identifying the energy of detected X-rays and obtaining a spectrum.

As illustrated in FIG. 2, the charged particle detector 46 and the detector control unit C6 may be provided in the electron beam column 42 in some cases.

The probe unit 48 is used when taking out the lamella 10 fabricated on the wafer 1, and is controlled by the probe unit control unit C8. A potential can be supplied to the wafer 1 by bringing the probe unit 48 into contact with a surface of the wafer 1. If the purpose is to take out the lamella 10, nano-tweezers may be applied instead of the probe unit 48.

The integrated control unit C1 can communicate with each of the ion beam column control unit C2, the electron beam column control unit C3, the wafer stage control unit C4, the detector control unit C4, the sub-stage control unit C5, the detector control unit C6, the X-ray detector control unit C7, and the probe unit control unit C8, and controls an operation of the entire lamella fabrication device 40.

The integrated control unit C1 controls the respective control units C2 to C8 according to instructions from the host control unit C0, and instructs the respective control units C2 to C8 on processing conditions, observation conditions, and the like of the wafer 1. Processing information and observation results obtained by the lamella fabrication device 40 are transmitted from the integrated control unit C1 to the host control unit C0.

To make the explanation easier to understand in the application, although the control units C2 to C8 are illustrated individually near control targets respectively associated with the control units, the respective control units C2 to C8 may be grouped into one control unit as a part of the integrated control unit C1.

The input device 50 is a device for the user to input instructions, for example, input of information on an analysis target, change of irradiation conditions of the ion beam IB and the electron beam EB1, and change of positions of the wafer stage 44 and the sub-stage 45, and the like. The input device 50 is, for example, a keyboard or mouse.

A GUI screen 52 and the like are displayed on the display 51. The GUI screen 52 is a screen for controlling each configuration of the lamella fabrication device 40. When various instructions are input to the GUI screen 52 by the input device 50, the instructions described above are transmitted to the integrated control unit C1 via the host control unit C0. The display 51 can display, as the GUI screen 52, for example, a screen for inputting the information on the analysis target, a screen illustrating a state of each configuration of the lamella fabrication device 40, a screen displaying the information on the analysis target obtained by observation, an instruction screen for changing the irradiation conditions of the ion beam IB and the electron beam EB1, an instruction screen for changing the position of the wafer stage 44, and the like. One display 51 may be provided, or a plurality of displays 51 may be provided.

Although not illustrated, the sample chamber 43 may be mounted with a gas deposition unit other than the components described above. Each gas deposition unit includes a control unit for controlling its drive. The gas deposition unit is used for fabricating or marking a protective film on the wafer 1 and stores a deposition gas that forms a deposited film by irradiation with the charged particle beam. The deposition gas can be supplied from a tip of a nozzle as needed. The sample chamber 43 may be mounted with a decompression device for air evacuation, a cold trap, an optical microscope, or the like. The sample chamber 43 may also be mounted with other detectors such as a tertiary electron detector, a STEM detector, a backscattered electron detector, a low energy loss electron detector, or the like.

### <Lamella Mounting Device>

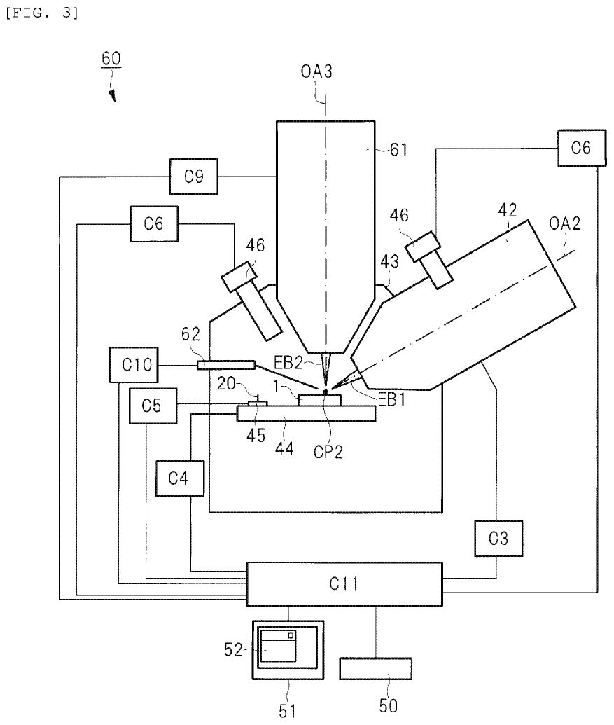

FIG. 3 is a schematic diagram illustrating the lamella mounting device 60 according to Embodiment 1. The lamella mounting device 60 is configured with a charged particle beam device such as the SEM device including two electron beam columns, for example. Many configurations included in the lamella mounting device 60 and their operations are substantially the same as in the case of the lamella fabrication device 40, and thus detailed description thereof will be omitted here.

The lamella mounting device 60 includes an electron beam column 61 and an electron beam column control unit C9 instead of the ion beam column 41 and the ion beam column control unit C2 of the lamella fabrication device 40. The lamella mounting device 60 includes nano-tweezers (tweezers) 62 and a nano-tweezers control unit C10.

Similar to the electron beam column 42, the electron beam column 61 includes all components necessary for the SEM device, such as an electron source for generating an electron beam (charged particle beam) EB2, a lens for focusing the electron beam EB2, and a deflection system for scanning and shifting the electron beam EB2. The electron source of the electron beam column 61 used in the lamella mounting device 60 may be a field emission type, a Schottky type or thermionic type.

The electron beam column control unit C9 controls the electron beam column 61. For example, the generation of the electron beam EB2 from the electron source, driving of the deflection system, and the like are controlled by the electron beam column control unit C9.

The electron beam EB1 emitted from the electron beam column 42 and the electron beam EB2 emitted from the electron beam column 61 are mainly focused on a cross point CP2, which is the intersection of the optical axis OA2 of the electron beam column 42 and an optical axis OA3 of the electron beam column 61. Since the lamella mounting device 60 includes the electron beam column 42 and the electron beam column 61, it becomes possible to observe the wafer 1, the lamella 10, and the mesh 20 from two directions.

Two electron beam columns are used in Embodiment 1, but as long as image observation of the wafer 1, the lamella 10, and the mesh 20 from two directions is possible, an ion beam column, optical microscope, AFM, or the like may be used instead of two electron beam columns. One or both of the two electron beam columns may be the ion beam column.

The nano-tweezers 62 are used when taking out the lamella 10 fabricated on the wafer 1, and are controlled by the probe unit control unit C10. The nano-tweezers 62 may be provided with a contact detection function to the surface of the wafer 1, a stress sensor, or the like.

The mesh 20 is mounted on the sub-stage 45. The positions and orientations of the wafer 1, the sub-stage 45 and the mesh 20 can be freely changed by the planar movement, vertical movement, rotating movement and tilting movement of the wafer stage 44.

On the wafer stage 44, a plurality of lamellae 10 are sequentially taken out from the wafer 1 by the nano-tweezers 62, and the lamellae 10 gripped by the nano-tweezers 62 are mounted on the mesh 20.

An integrated control unit C11 controls the respective control units C3 to C6, C9, and C10 according to instructions from the host control unit C0, and instructs the respective control units C3 to C6, C9, and C10 on the conditions for mounting the lamella 10, and the like. The mounting result obtained by the lamella mounting device 60 is transmitted from the integrated control unit C11 to the host control unit C0. The respective control units C3 to C6, C9, and C10 may be integrated into one control unit as a part of the integrated control unit C11.

### <Lamella Analysis Device>

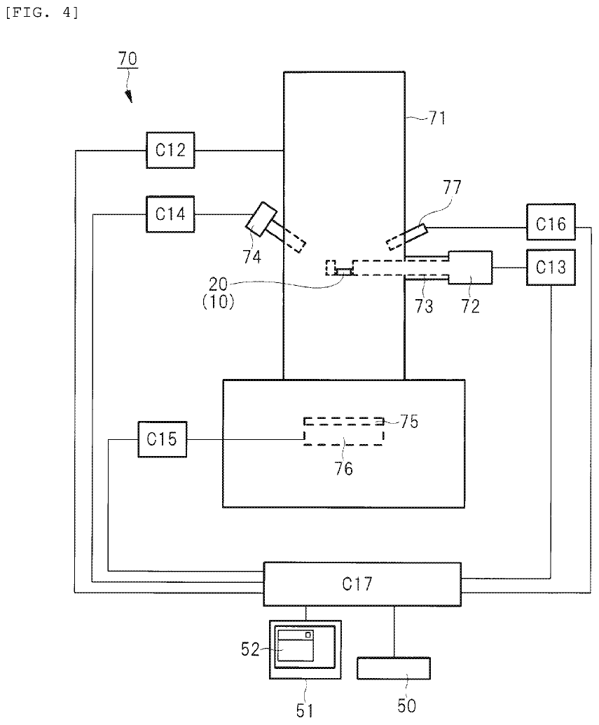

FIG. 4 is a schematic diagram illustrating the lamella analysis device 70 according to Embodiment 1. The lamella analysis device 70 is configured with a charged particle beam device such as a TEM device or a STEM device, for example.

The lamella analysis device 70 includes an electron beam column 71, a sample stage 72, a holder 73, a charged particle detector 74, a fluorescent plate 75, a camera 76, an X-ray detector 77, and control units C12 to C17. The input device 50 and the display 51 are provided inside or outside the lamella analysis device 70.

The electron beam column 71 includes all components necessary for the TEM device or the STEM device, such as an electron source for generating an electron beam, a lens for focusing the electron beam, and a deflection system for scanning and shifting the electron beam. The lamella 10 mounted on the mesh 20 is irradiated with the electron beam passing through the electron beam column 71.

The electron beam column control unit C12 controls the electron beam column 71. Specifically, the generation of the electron beam by the electron source of the electron beam column 71 and the driving of the deflection system are controlled by the electron beam column control unit C12.

The holder 73 is provided on the sample stage 72, and the mesh 20 can be placed on the holder 73. The driving of the sample stage 72 is controlled by the sample stage control unit C13, and the sample stage 72 can perform planar movement, vertical movement, or rotating movement. By driving the sample stage 72, the position and orientation of the holder 73 are changed, and the position and orientation of the lamella 10 mounted on the mesh 20 are also changed.

The charged particle detector 74 detects charged particles generated when the lamella 10 is irradiated with the electron beam. A composite charged particle detector capable of detecting not only electrons but also ions may be used as the charged particle detector 74. The X-ray detector 77 detects X-rays emitted by the lamella 10.

The detector control unit C14 can control the charged particle detector 74, and includes a circuit or an arithmetic processing unit that arithmetically processes a detection signal from the charged particle detector 74 and forms an image. The X-ray detector control unit C16 can control the X-ray detector 77, and includes an arithmetic processing unit for identifying the energy of the detected X-rays and obtaining a spectrum.

The transmitted electrons transmitted through the lamella 10 collide with the fluorescent plate 75, and a transmission type electron microscope image is projected. The camera 76 images the fluorescent plate 75. The camera control unit C15 controls an operation of the camera 76.

The integrated control unit C17 can communicate with each of the electron beam column control unit C12, the sample stage control unit C13, the detector control unit C14, the camera control unit C15, and the X-ray detector control unit C16, and controls an operation of the entire lamella analysis device 70.

The integrated control unit C17 controls the respective control units C12 to C16 according to instructions from the host control unit C0, and instructs the respective control units C12 to C16 on analysis conditions, and the like of the lamella 10. An analysis result obtained by the lamella analysis device 70 is transmitted from the integrated control unit C17 to the host control unit C0. The control units C12 to C16 may be integrated into one control unit as a part of the integrated control unit C17.

A cold trap may be disposed near the mesh 20 (lamella 10), and the holder 73 may be provided with a cooling mechanism, a heating mechanism, a gas introducing mechanism, and the like.

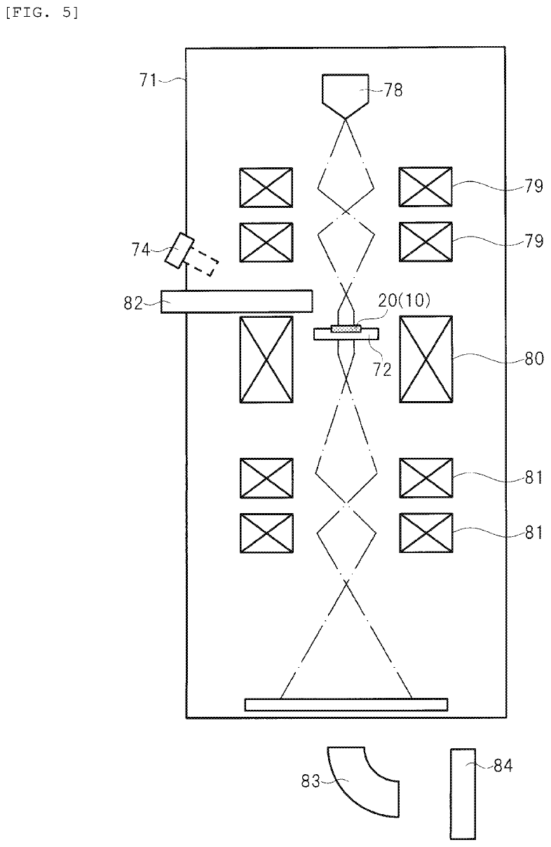

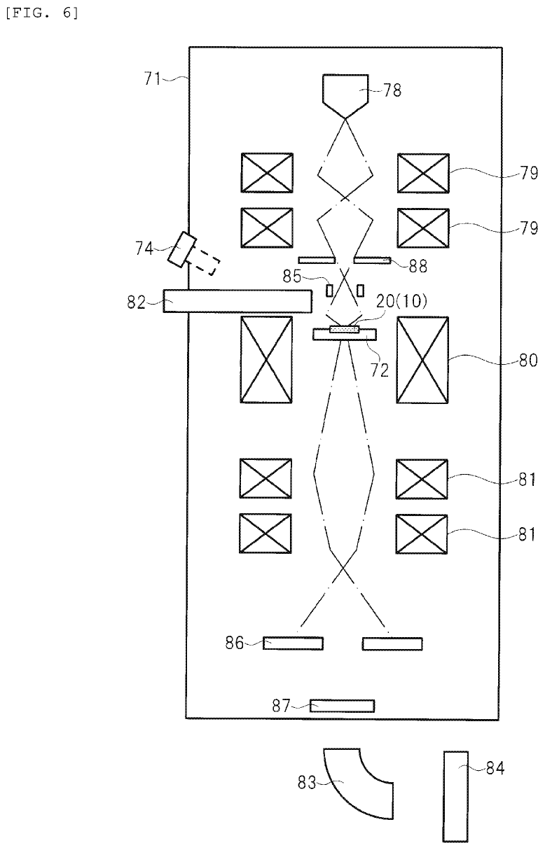

FIG. 5 is a schematic diagram when the lamella analysis device 70 is a TEM device, and FIG. 6 is a schematic diagram when the lamella analysis device 70 is a STEM device.

As illustrated in FIGS. 5 and 6, the electron beam column 71 includes an electron source 78 for generating an electron beam, an irradiation lens group 79 for irradiating the lamella 10 with the electron beam, an objective lens 80, a projection lens group 81 for projecting transmitted electrons, an X-ray detector 82 for detecting X-rays emitted from the lamella 10, an electron energy loss spectrometer (EELS) 83, and an EELS detector 84.

The electron beam column 71 is mounted with all elements necessary for analysis, such as a deflection system 85 for scanning or shifting the electron beam, an annular detector 86 for detecting transmission electrons scattered at a wide angle, a transmission electron detector 87 for detecting the transmission electrons, a diaphragm 88 for controlling a divergence angle of the electron beam, and the like.

In the case of the TEM mode, as illustrated in FIG. 5, information on the lamella 10 is acquired by irradiating the entire observation region on the sample with an electron beam and obtaining a projection image, an interference image, a diffraction pattern, and the like. On the other hand, in the case of the STEM mode, as illustrated in FIG. 6, information on the lamella 10 is acquired by focusing the electron beam on the lamella 10 and scanning the observation region.

### <Host Control Unit>

As illustrated in FIG. 1, the host control unit C0 includes a memory C0a, a processing end determination unit C0b that evaluates a fabrication result of the lamella 10, and an analysis result determination unit C0c that evaluates an analysis result of the lamella 10. The memory C0a is a storage device configured with a nonvolatile memory, a hard disk, or the like.

In the memory C0a, FIB processing conditions corresponding to the lamella 10 are stored. The FIB processing conditions include, for example, an ion beam acceleration voltage, a beam current, a processing region on the wafer 1, a processing order, and the like.

In the memory C0a, analysis conditions corresponding to each lamella 10 are stored. The analysis conditions include multiple items.

In the case of the TEM mode, the analysis conditions include, for example, observation modes, TEM magnification, camera length, probe current amount (size of diaphragm diameter of irradiation system), and the like. The observation modes include, for example, TEM image observation, diffraction pattern observation, energy dispersion type X-ray analysis (EDX analysis), electron energy loss spectroscopic analysis (EELS analysis), and the like.

In the case of the STEM mode, the analysis conditions include, for example, observation magnification, probe diameter (reduction ratio of optical system), irradiation angle to the lamella 10, selection of detector (transmission electron detector, annular detector, secondary electron detector, and the like), capture angle of the detector, and the like.

The processing end determination unit C0b and the analysis result determination unit C0c may be configured by hardware, implemented on a processor by executing software, or configured by combining hardware and software.

The memory C0a of the host control unit C0 can store analysis position data D1, lamella fabrication position data D2, lamella mounting position data D3 and analysis data D4 illustrated in FIG. 1.

The analysis position data D1 is data indicating a position on the wafer 1 where cross-sectional analysis is scheduled to be performed, and includes the processing condition and the observation condition of the lamella 10. The lamella fabrication position data D2 is data indicating the position on the wafer 1 where the lamella 10 has been successfully fabricated, and includes processing information and observation result of the lamella 10. The lamella mounting position data D3 is data indicating a position of the lamella 10 mounted on the mesh 20, and includes mounting conditions of the lamella 10. The analysis data D4 is data containing an analysis result, and is data containing detection signals of charged particles or X-rays from the lamella 10 irradiated with the electron beam, an observation image obtained from the detection signals, and the like.

Respective pieces of information on the analysis position data D1, the lamella fabrication position data D2, the lamella mounting position data D3, and the analysis data D4 are associated with each other. That is, it is possible to know at what position on the mesh 20 the lamella 10 fabricated at a predetermined position on the wafer 1 is mounted and what the analysis result of the lamella 10 is.

As described later, a plurality of lamellae 10 having various shapes exists, and each of the data D1 to D4 includes not only position data but also shape data indicating which shape the lamella 10 has.

For example, the memory C0a stores a plurality of mounting methods each corresponding to the shape of each lamella 10. The host control unit C0 can acquire information about the shape of the lamella 10 from the lamella fabrication device 40 based on the lamella fabrication position data D2. The host control unit C0 can designate a mounting method according to the shape of the lamella 10 to the lamella mounting device 60 among a plurality of mounting methods for mounting the lamella 10 on the mesh 20.

By the way, the host control unit C0 can comprehensively control the general control unit C1 of the lamella fabrication device 40, the general control unit C11 of the lamella mounting device 60, and the general control unit C17 of the lamella analysis device 70, and control respective operations performed thereby. Therefore, in the application, the host control unit C0 may be simply referred to as a “control unit” as a control unit that controls the control units C1 to C17.

### <Lamella>

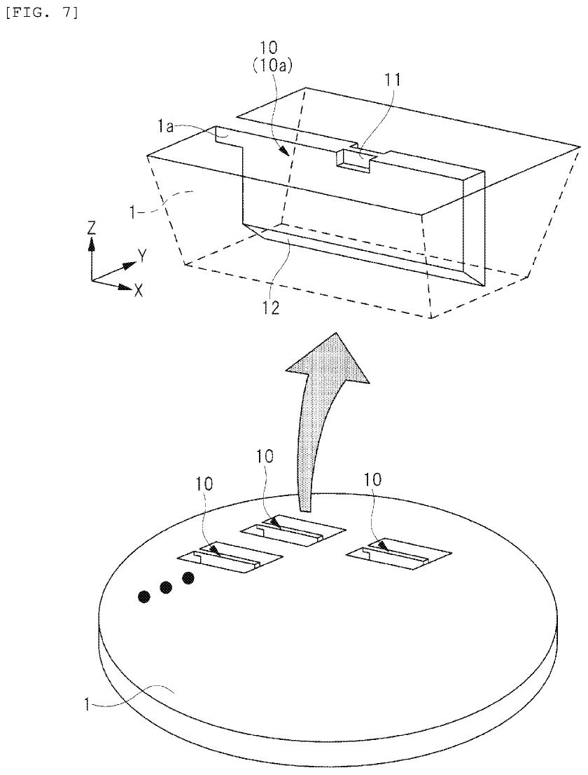

The lamella 10 used in Embodiment 1 will be described below with reference to FIG. 7.

As illustrated in FIG. 7, the lamella 10 is fabricated by etching a part of the wafer 1 with the lamella fabrication device 40. During fabrication, the lamella 10 is connected to the wafer 1 at a connection location 1a. The number of connection locations 1a is not limited to one, and may be two or more.

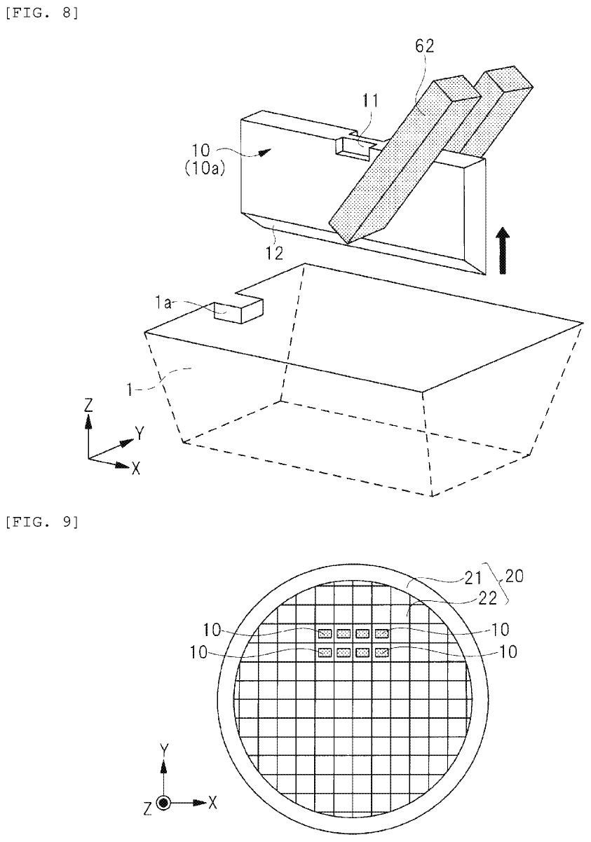

At the time of FIG. 7, the lamella 10, the connection location 1a and the wafer 1 are integrated, but when the lamella 10 is mounted on the mesh 20, the lamella 10 is gripped and picked up by the nano-tweezers 62, as illustrated in FIG. 8. Therefore, the lamella 10 is separated from the connection location 1a.

The wafer 1 in Embodiment 1 is composed of a semiconductor substrate having a p-type or n-type impurity region formed thereon, a semiconductor element such as a transistor formed on the semiconductor substrate, a wiring layer formed on the semiconductor element, and the like. The state of the wafer 1 includes a case where the semiconductor substrate, the semiconductor elements, the wiring layer, and the like are completed, and a case where the semiconductor substrate, the semiconductor elements, the wiring layer, and the like are in the process of being fabricated. Since the lamella 10 is a thin piece obtained from a part of the wafer 1, a structure of the lamella 10 includes all or part of the semiconductor substrate, the semiconductor element, and the wiring layer. In Embodiment 1, the wafer 1 that is mainly manufactured in a semiconductor manufacturing line is described, but the wafer 1 may also be a structure that is used other than a semiconductor technology.

The lamella 10 is a thin piece sample whose width in the Y-direction is thinner than the width in the X-direction and the width in the Z-direction. The lamella 10 includes a body 10a and an analysis region 11 provided in a part of the body 10a. The analysis region 11 is a region to be analyzed by the lamella analysis device 70. The width of the analysis region 11 in the Y-direction is different from the width of the body 10a in the Y-direction and is thinner than the width of the body 10a in the Y-direction.

The body 10a also includes a notched region 12 whose width in the Y-direction continuously decreases as is far from the distance from the analysis region 11. The notched region 12 is a region processed so that the lamella 10 can be easily separated from the wafer 1 when the lamella 10 is taken out by the nano-tweezers 62.

The size of the wafer 1 is 100 mm to 300 mm in diameter. Regarding the size of the lamella 10, the width in the X-direction and the width in the Z-direction are approximately several μm to several tens of μm, respectively, and the width in the Y-direction is approximately several μm. The width of the analysis region 11 in the Y-direction is several nanometers to several tens of nanometers.

### <Mesh>

The mesh 20 used in Embodiment 1 will be described below with reference to FIG. 9.

FIG. 9 illustrates a state in which a plurality of lamellae 10 are mounted on the mesh 20. The mesh 20 includes a substrate 21 formed with a large number of holes and forming a lattice shape (grid), and a film 22 formed on the substrate 21. The film 22 is, for example, a carbon film or a polymer resin film, and has a property of transmitting electrons. The lamella 10 is brought into close contact with and supported by the film 22. The film 22 forms a flat surface and the lamella 10 is supported on the flat surface.

The mesh 20 can be configured by the film 22 alone by forming the film 22 itself into the lattice shape. One lamella 10 may be supported by one lattice, or a plurality of lamellae 10 may be supported by one lattice. The mesh 20 in FIG. 9 is a full-moon type and has a circular shape. However, the shape of the mesh 20 is not limited to the circular shape, and may be a polygonal shape or any shape.

### <Processing Flow of Analysis System>

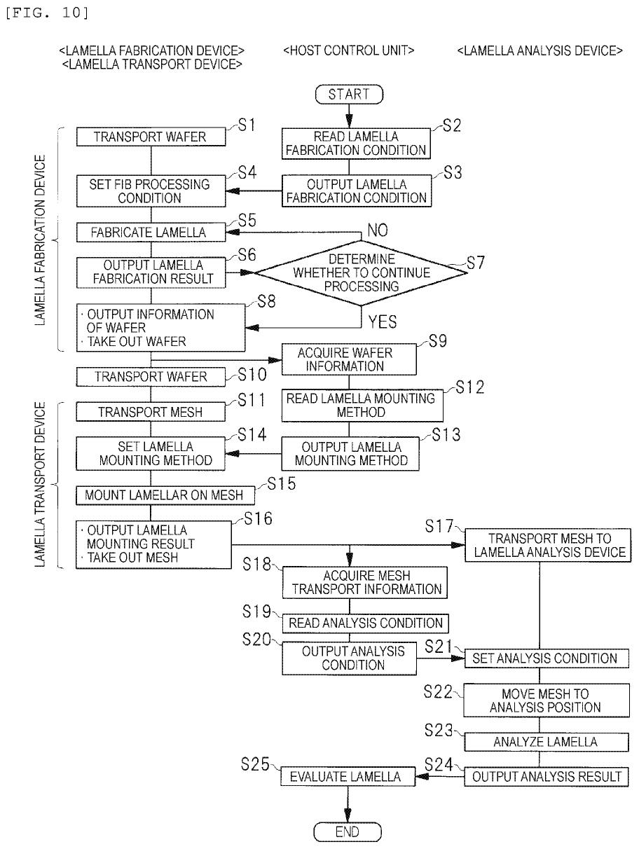

FIG. 10 is a processing flow diagram of the analysis system 30 according to Embodiment 1. In FIG. 10, respective steps are illustrated corresponding to the lamella fabrication device 40, the lamella mounting device 60, the host control unit C0, and the lamella analysis device 70.

In step S1, the wafer 1 desired to be subjected to cross-sectional analysis is transported from the semiconductor manufacturing line to the lamella fabrication device 40, and the transported wafer 1 is placed on the wafer stage 44 of the lamella fabrication device 40.

In step S2, the host control unit C0 reads the processing conditions and observation conditions of the lamella 10 that is included in the analysis position data D1. Data about the shape of the lamella 10 is also read out.

In step S3, the host control unit C0 outputs the read information to the lamella fabrication device 40. In step S4, the lamella fabrication device 40 sets the processing conditions of the lamella 10 based on the output information.

In step S5, the wafer stage 44 moves to the analysis position based on the processing conditions. Next, the wafer 1 is irradiated with the ion beam IB from the ion beam column 41 to etch the periphery of a region on the wafer 1 desired to be subjected to the cross-sectional analysis, thereby fabricating the body 10a forming an outer shape of the lamella 10. Next, the analysis region 11 is fabricated on an upper portion of the lamella 10 by etching a part of the body 10a. The analysis region 11 is subjected to surface finish treatment for later analysis.

In step S6, the lamella fabrication device 40 outputs the processing information and observation result of the lamella 10 to the host control unit C0 as the lamella fabrication position data D2. The lamella fabrication position data D2 also includes information about the shape of the lamella 10. The pieces of information may be, for example, an SEM image, an intensity change of an electrical signal at a specific location, and the like. The intensity change of the electrical signal may be a signal depending on the thickness of the lamella 10, or may be the intensity change due to repeated exposure and disappearance of the structure forming the lamella 10.

In step S7, the processing end determination unit C0b of the host control unit C0 determines whether processing of the wafer 1 should be continued or ended based on the above information. For the determination here, for example, an image matching method or the like is used. In the image matching method, for example, whether processing is necessary is determined by whether a processed cross-sectional image (SEM image) of the lamella 10 matches a reference image prepared in advance.

When the processed cross-sectional image of the lamella 10 does not match the reference image (NO), it is determined that the processing has not been completed, and the process returns to step S5 to continue the FIB processing. On the other hand, when the processed cross-sectional image of the lamella 10 matches the reference image (YES), it is determined that the processing has ended, and step S8 is executed.

The movement of the wafer stage 44 and the fabrication of the lamella 10 as described above are performed for all regions corresponding to the analysis position data D1 on the wafer 1 being processed. That is, steps S5 to S7 are repeated until the fabrication of all lamellae 10 corresponding to the analyzed position data D1 is ended.

In step S8, the wafer 1 on which the fabrication of the lamella 10 has been ended is taken out from the lamella fabrication device 40. The lamella fabrication device 40 outputs information on the wafer 1 to the host control unit C0, and the host control unit C0 acquires the information on the wafer 1, in step S9. The outputting of the information on the wafer 1 and the taking out of the wafer 1 do not have to be performed at the same time.

In step S10, the wafer 1 on which a plurality of lamellae 10 are fabricated is transported from the lamella fabrication device 40 to the lamella mounting device 60. In step S11, the mesh 20 is transported to the lamella mounting device 60. Steps S10 and S11 are performed in parallel.

In step S12, the host control unit C0 reads a mounting method of the lamella 10. In step S13, based on information about the shape of the lamella 10, the host control unit C0 designates a mounting method according to the shape of the lamella 10 to the lamella mounting device 60 among a plurality of mounting methods for mounting the lamella 10 on the mesh 20. The host control unit C0 outputs the lamella fabrication position data D2 corresponding to the received wafer 1 to the lamella mounting device 60 together with the mounting method.

When the lamella mounting device 60 stores a plurality of mounting methods, for the mounting method stored in the host control unit C0, the mounting method stored in the lamella mounting device 60 may be specified by an ID or the like.

In step S14, the lamella mounting device 60 sets, based on the information output from the host control unit C0, driving conditions for each configuration included in the lamella mounting device 60 to perform the mounting method designated by the host control unit C0.

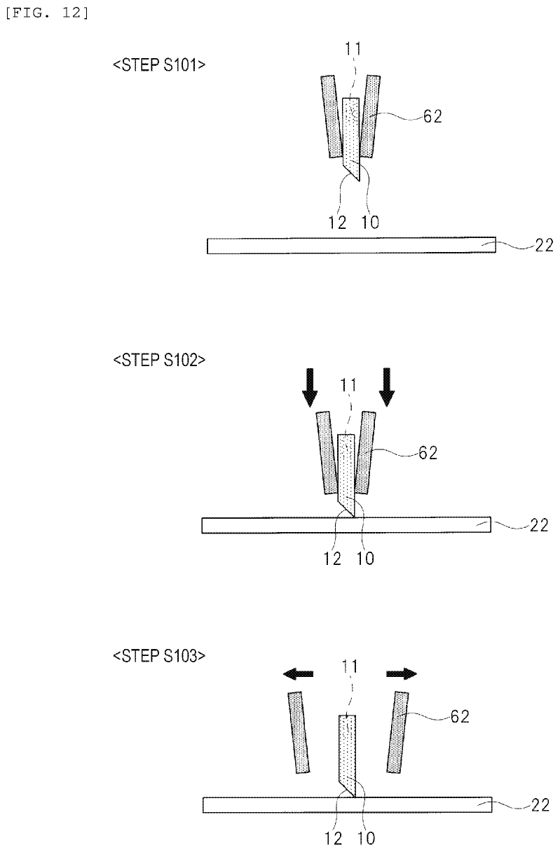

In step S15, the lamella 10 is mounted on the mesh 20 by the designated mounting method. The mounting method of the lamella 10 will be described later in detail with reference to FIGS. 12 to 14. The mounting method may differ depending on the shape of the lamella 10, and other such mounting methods will be described in other embodiments.

In step S16, the mounting result of the lamella 10 is output from the lamella mounting device 60 to the host control unit C0 together with the lamella mounting position data D3. The mesh 20 on which the lamella 10 is mounted is taken out from the lamella mounting device 60.

In step S17, the taken out mesh 20 is transported from the lamella mounting device 60 to the lamella analysis device 70. In step S18, the host control unit C0 acquires transport information on the mesh 20. The transport information may be, for example, an ID of the mesh 20, an ID of the wafer 1 corresponding to the lamella 10 mounted on the mesh 20, and the like. Steps S17 and S18 are performed in parallel.

In step S19, the host control unit C0 reads the analysis conditions from the memory C0a. In step S20, the host control unit C0 outputs the read analysis conditions to the lamella analysis device 70. After that, in step S21, the lamella analysis device 70 sets the analysis conditions based on the output analysis conditions.

In step S22, the mesh 20 is placed on the holder 73, and the sample stage 72 is driven to move the mesh 20 to a predetermined observation position.

In step S23, while the mesh 20 is being placed on the holder 73 so that the analysis region 11 faces the electron source 78, the analysis region 11 is analyzed by being irradiated with an electron beam from the electron source 78 under the set analysis conditions.

In step S24, the lamella analysis device 70 outputs the analysis result of the lamella 10 as the analysis data D4 to the host control unit C0. In step S25, the analysis result determination unit C0c of the host control unit C0 evaluates the lamella 10 based on the analysis data D4. When all the lamellae 10 mounted on the mesh 20 have been evaluated, the mesh 20 is taken out from the lamella analysis device 70.

### <Lamella Mounting Method>

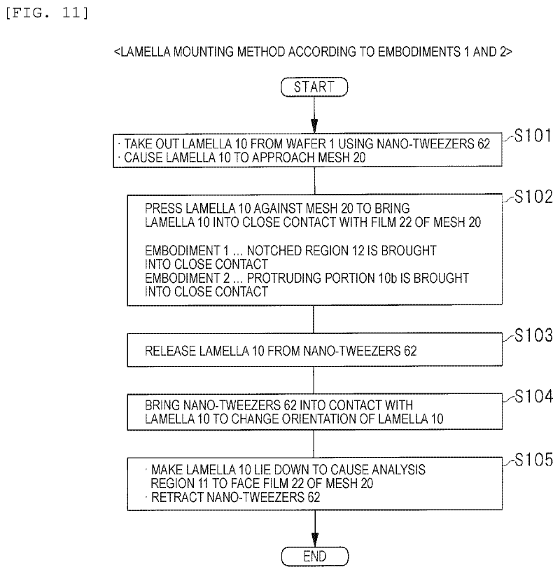

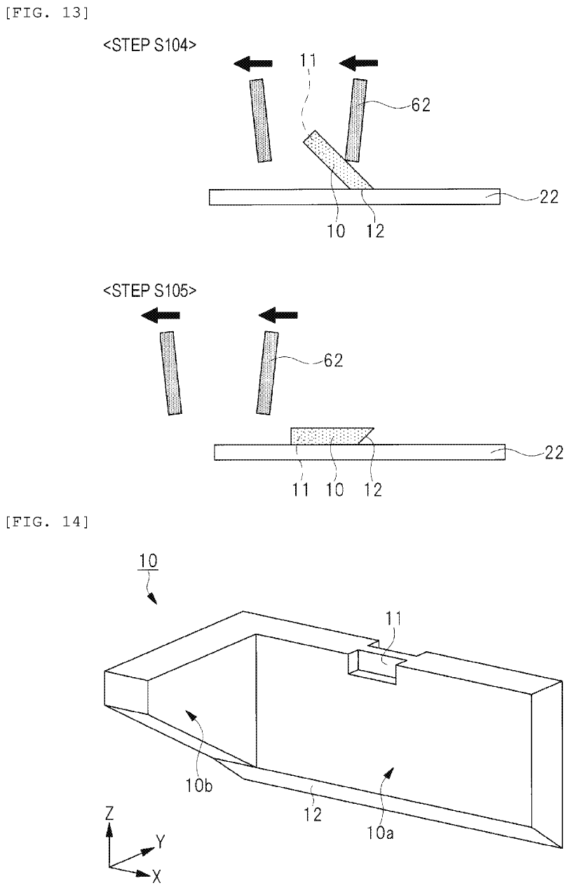

The mounting method of the lamella 10 according to Embodiment 1 indicated in step S15 will be described in detail below with reference to FIGS. 11 to 13. FIG. 11 is a processing flow diagram of the lamella mounting method according to Embodiments 1 and 2. Steps S101 to S105 illustrated in FIGS. 12 and 13 correspond to steps S101 to S105 in FIG. 11.

In step S101, first, the nano-tweezers 62 grip the lamella 10 fabricated on a part of the wafer 1 and take out the lamella 10 from the wafer 1. Next, the nano-tweezers 62 are brought closer to the mesh 20. To bring the nano-tweezers 62 closer to the mesh 20, the nano-tweezers 62 may be moved under the control of the nano-tweezers control unit C10, or the mesh 20 may be moved using the sub-stage 45 and the wafer stage 44 together.

The mesh 20 is placed on the sub-stage 45, and by driving the sub-stage 45, the orientation of the mesh 20 can be freely adjusted, such as tilting the mesh 20 by 90 degrees. As means for tilting the mesh 20, an L-shaped holder may be used.

In step S102, the nano-tweezers 62 are moved to press the lamella 10 against the film 22 contained in the mesh 20 while the lamella 10 is being gripped by the nano-tweezers 62. Therefore, the lamella 10 is brought into close contact with the film 22. In Embodiment 1, the notched region 12 is brought into close contact with the mesh 20. At this point, the analysis region 11 does not face the film 22.

By pressing the lamella 10 against a designated location on the film 22 for several seconds, a force (adhesion force) such as an intermolecular force is generated between a bottom surface (notched region 12) of the lamella 10 and the designated location on the film 22, thereby capable of bringing the lamella 10 into close contact with the designated location of the film 22. The information on the designated location of the film 22 is included in the mounting conditions output from the host control unit C0.

In the case of the shape of the notched region 12, the lamella 10 may be brought into close contact with the film 22 while the lamella 10 is not perpendicular to the film 22 but is tilted.

The user can check contact between the bottom surface of the lamella 10 and the designated location of the film 22 by viewing the GUI screen 52 of the display 51 or by a method of detecting the contact using a contact detection sensor or the like.

The adhesion force between the lamella 10 and the film 22 includes not only intermolecular force but also Coulomb force and electrostatic force. The adhesion force is a relatively large force, and is larger than the adhesion force between the nano-tweezers 62 and the lamella 10 when the nano-tweezers 62 are gripping the lamella 10. In other words, an area where the lamella 10 is brought into close contact with the film 22 is larger than an area where the tips of the nano-tweezers 62 are in contact with the lamella 10.

Therefore, even if the lamella 10 is released from the nano-tweezers 62, the lamella 10 does not fall down. For example, when the mesh 20 (film 22) is disposed along a direction parallel to gravity and the lamella 10 is brought into close contact with the film 22 in a direction perpendicular to gravity, even if the lamella 10 is released from the nano-tweezers 62, the lamella 10 does not fall and is supported by the film 22.

In step S103, the tip portions of the nano-tweezers 62 are opened to release the lamella 10 from the nano-tweezers 62. Here, the lamella 10 is supported by the film 22, as described above.

In step S104, the orientation of the lamella 10 is changed by moving the nano-tweezers 62 and bringing the nano-tweezers 62 into contact with the lamella 10. That is, the nano-tweezers 62 are moved to make the lamella 10 lie down.

The adhesion force between the film 22 and the lamella 10 is greater than the adhesion force between the nano-tweezers 62 and the lamella 10 when the nano-tweezers 62 are in contact with the lamella 10. Therefore, the mounting position of the lamella 10 can be prevented from being moved together with the nano-tweezers 62 as the nano-tweezers 62 are moved.

In step S105, following step S104, the nano-tweezers 62 are further moved. Therefore, the lamella 10 is laid down, and the lamella 10 becomes horizontal with the film 22. That is, the lamella 10 is brought into close contact with the film 22 so that the analysis region 11 faces the film 22. Next, the nano-tweezers 62 are moved away from the mesh 20.

Thus, the process of mounting the lamella 10 on the mesh 20 is completed.

As described above, according to the mounting method of the lamella 10 according to Embodiment 1, many lamellae 10 can be mounted on the mesh 20, which can mount more lamellae than a half-moon type lamella carrier, using the nano-tweezers 62. Accordingly, the transport throughput can be improved as compared with the case of adopting the half-moon type lamella carrier. Since a commercially available product (same as conventional product) can be used as the mesh 20 according to Embodiment 1, the running cost can be reduced.

By applying such mounting method to the analysis system 30, the throughput of quality evaluation of the wafer can be improved. Since the process of mounting the lamella 10 on the mesh 20 can be automated, the transport throughput can be further improved, and the user's labor can be reduced.

### Embodiment 2

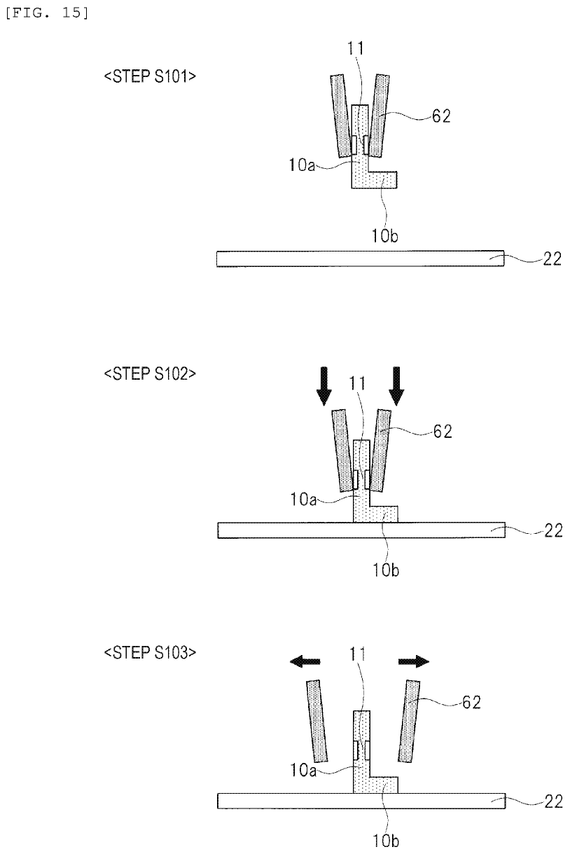

The lamella 10 and the mounting method of the lamella 10 according to Embodiment 2 will be described below with reference to FIGS. 14 to 16. In the following description, differences from Embodiment 1 will be mainly described, and descriptions of points that overlap with Embodiment 1 will be omitted.

As illustrated in FIG. 14, the lamella 10 according to Embodiment 2 further includes a protruding portion 10b that protrudes from the body 10a in the Y-direction. The width of the protruding portion 10b in the Y-direction is wider than the width of the body 10a in the Y-direction. Thus, the lamella 10 according to Embodiment 2 forms an L shape with the body 10a and the protruding portion 10b.

Such lamella 10 is fabricated by the lamella fabrication device 40, and information on the shape of the lamella 10 is stored as a part of the lamella fabrication position data D2. Based on the acquired shape information on the lamella 10, the host control unit C0 designates the mounting method for mounting the L-shaped lamella 10 on the mesh 20 to the lamella mounting device 60.

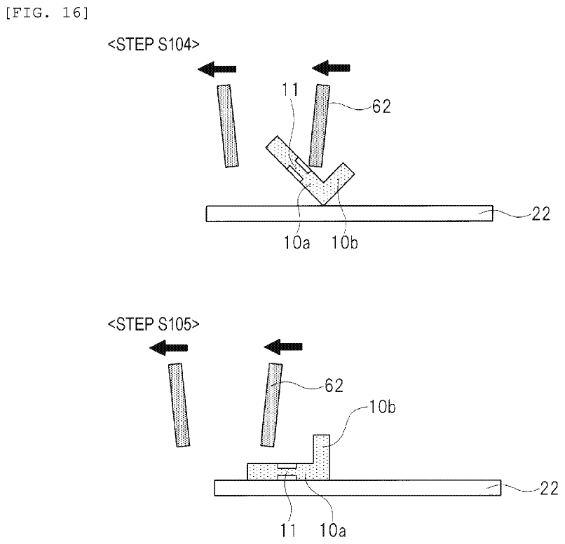

The mounting method of the lamella 10 according to Embodiment 2 will be described below with reference to FIGS. 15 and 16. As illustrated in FIG. 11, the mounting method of lamella according to Embodiment 2 is performed in substantially the same manner as in Embodiment 1 except for some parts. Steps S101 to S105 illustrated in FIGS. 15 and 16 correspond to steps S101 to S105 in FIG. 11.

In step S101, first, the nano-tweezers 62 grip the lamella 10 fabricated on a part of the wafer 1 and take out the lamella 10 from the wafer 1. Here, the body 10a is gripped by the nano-tweezers 62 so that the protruding portion 10b faces the film 22. Next, the nano-tweezers 62 are brought closer to the mesh 20.

In step S102, the nano-tweezers 62 are moved to press the lamella 10 against the film 22 while the body 10a of the lamella 10 is being gripped by the nano-tweezers 62. Therefore, the lamella 10 is brought into close contact with the film 22. In Embodiment 2, the protruding portion 10b is brought into close contact with the mesh 20. At this point, the analysis region 11 does not face the film 22.

Also in Embodiment 2, the lamella 10 and the film 22 are brought into close contact with each other by a force such as the intermolecular force. In Embodiment 2, since the protruding portion 10b is in close contact with the film 22, the contact area between the lamella 10 and the film 22 is increased as compared with the notched region 12 of Embodiment 1. Accordingly, the adhesion force between the lamella 10 and the film 22 can be increased.

Subsequent steps S103 to S105 are substantially the same as in Embodiment 1. In step S103, the lamella 10 is released from the nano-tweezers 62. Here, the lamella 10 is supported by the film 22, as described above. In step S104, the orientation of the lamella 10 is changed by moving the nano-tweezers 62 and bringing the nano-tweezers 62 into contact with the lamella 10.

In step S105, following step S104, the nano-tweezers 62 are further moved. Therefore, the lamella 10 is laid down, and the lamella 10 becomes horizontal with the film 22. That is, the lamella 10 is brought into close contact with the film 22 so that the analysis region 11 faces the film 22. Next, the nano-tweezers 62 are moved away from the mesh 20.

As in Embodiment 2, by providing the protruding portion 10b capable of ensuring a wide contact area, when the film 22 is in an upright position, that is, a state in which a contact surface between the film 22 and the lamella 10 is parallel to the direction of the gravitational field, the lamella 10 can be brought into contact with the film 22. The same applies to Embodiments 3 and 4 described later.

The lamella 10 is notched from the wafer 1 or the like by cutting processing with the ion beam IB, and is picked upward by a gripping mechanism such as the nano-tweezers 62 or the like after the cutting processing with the ion beam IB. By setting the film 22 in an upright position, it is possible to bring the lamella 10 into contact with the film 22 while maintaining a gripped state during picking up. After the contact, the film 22 is laid down. That is, an attitude of the film 22 is changed so that a surface of the analysis region 11 is perpendicular to the optical axis OA3 of the electron beam EB2. Therefore, it is possible to prepare for observation without causing the gripping mechanism to perform complicated movements or performing operations such as changing gripping of the lamella 10.

By making the area of the contact surface between the protruding portion 10b and the film 22 larger than the area of the contact surface between the tweezers 62 and the lamella 10, the lamella 10 can be smoothly transferred using the intermolecular force.

### Embodiment 3

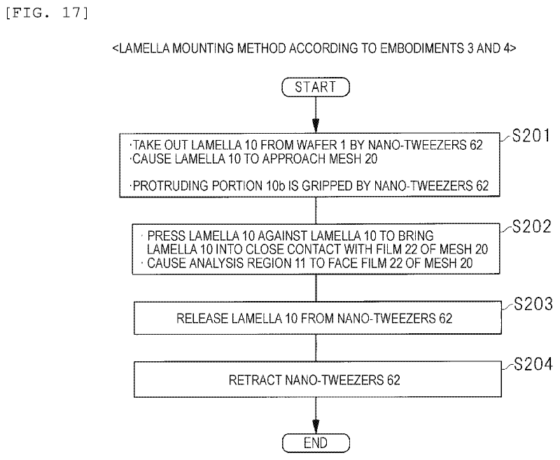

A mounting method of the lamella 10 according Embodiment 3 will be described below with reference to FIGS. 17 to 19. In the following description, differences from Embodiment 2 will be mainly described, and descriptions of points that overlap with Embodiment 2 will be omitted.

The lamella 10 used in Embodiment 3 is the L-shaped lamella 10 illustrated in FIG. 14 as in Embodiment 2. In Embodiment 3, the host control unit C0 designates another mounting method for mounting the L-shaped lamella 10 on the mesh 20 to the lamella mounting device 60.

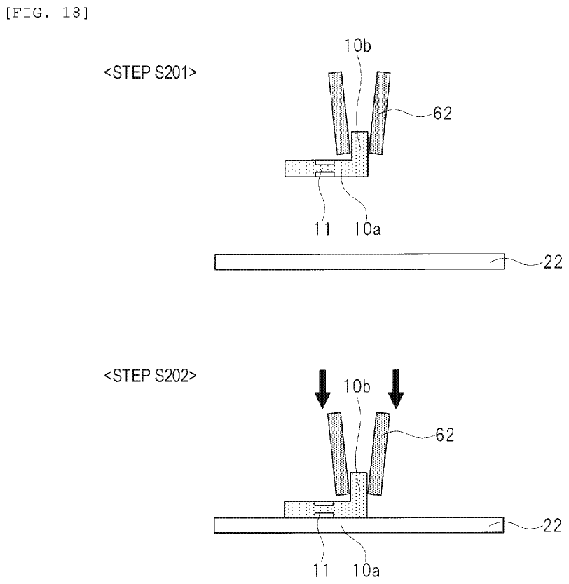

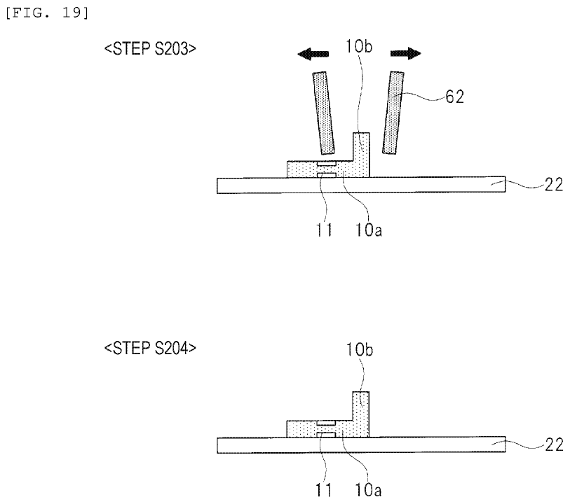

FIG. 17 is a processing flow diagram of a lamella mounting method according to Embodiments 3 and 4. Steps S201 to S204 illustrated in FIGS. 18 and 19 correspond to steps S201 to S204 in FIG. 17.

In step S201, first, the nano-tweezers 62 grip the lamella 10 fabricated on a part of the wafer 1 and take out the lamella 10 from the wafer 1. Here, the protruding portion 10b is gripped by the nano-tweezers 62 so that the analysis region 11 of the body 10a faces the film 22. Next, the nano-tweezers 62 are brought closer to the mesh 20.

In step S202, the nano-tweezers 62 are moved to press the lamella 10 against the film 22 while the protruding portion 10b of the lamella 10 is being gripped by the nano-tweezers 62. Therefore, the lamella 10 is brought into close contact with the film 22 so that the analysis region 11 faces the film 22. In Embodiment 3, the body 10a is brought into close contact with the mesh 20.

In step S203, the tip portions of the nano-tweezers 62 are opened to release the lamella 10 from the nano-tweezers 62. Here, the lamella 10 is supported by the film 22.

In step S204, the nano-tweezers 62 are moved away from the mesh 20.

Thus, in Embodiment 3, by gripping the protruding portion 10b by the nano-tweezers 62, the lamella 10 can be brought into close contact with the film 22 so that the analysis region 11 faces the film 22. Therefore, in Embodiment 3, since the number of mounting steps can be reduced compared to Embodiments 1 and 2, the transport throughput can be further improved. The analysis system 30 can further improve the throughput of quality evaluation of the wafer.

When the orientation of the lamella 10 is changed by moving the nano-tweezers 62, there is also a possibility that the mounting position of the lamella 10 will shift slightly. However, in Embodiment 3, since the body 10a is brought into direct contact with the film 22 without changing the direction of the lamella 10, such possibility can be prevented.

### Embodiment 4

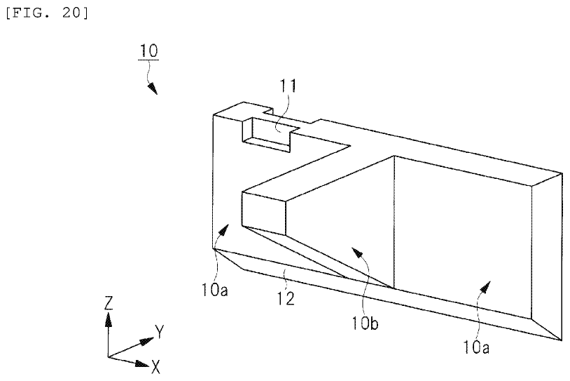

The lamella 10 and the mounting method of the lamella 10 according to Embodiment 4 will be described below with reference to FIGS. 20 to 22. In the following description, differences from Embodiment 3 will be mainly described, and descriptions of points that overlap with Embodiment 3 will be omitted.

As illustrated in FIG. 20, the lamella 10 according to Embodiment 4 is similar to Embodiment 3 and further includes the protruding portion 10b protruding from the body 10a in the Y-direction. The width of the protruding portion 10b in the Y-direction is wider than the width of the body 10a in the Y-direction. The protruding portion 10b according to Embodiment 4 is positioned near the center of the body 10a in the X-direction. Thus, the lamella 10 according to Embodiment 4 forms a T shape with the body 10a and the protruding portion 10b.

Such lamella 10 is fabricated by the lamella fabrication device 40, and information on the shape of the lamella 10 is stored as a part of the lamella fabrication position data D2. Based on the acquired shape information on the lamella 10, the host control unit C0 designates a mounting method for mounting the T-shaped lamella 10 on the mesh 20 to the lamella mounting device 60.

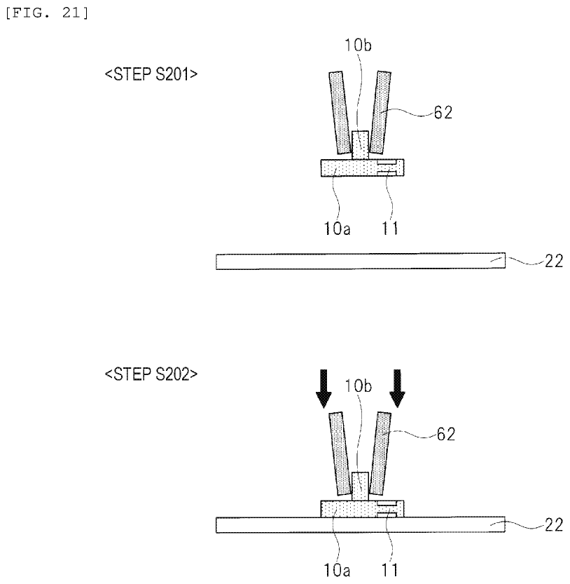

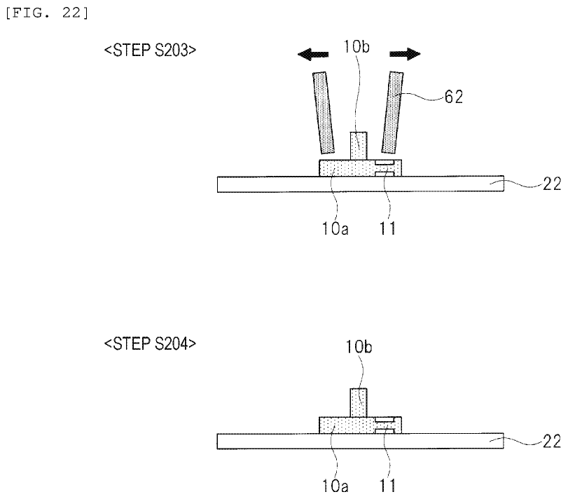

The mounting method of the lamella 10 according to Embodiment 4 will be described in detail below with reference to FIGS. 21 and 22. As indicated in FIG. 17, the lamella mounting method according to Embodiment 4 is performed in substantially the same manner as in Embodiment 3 except for a fabrication position of the protruding portion 10b. Steps S201 to S204 illustrated in FIGS. 21 and 22 correspond to steps S201 to S204 in FIG. 17.

In step S201, the lamella 10 is taken out from the wafer 1 while the protruding portion 10b is gripped by the nano-tweezers 62, and the nano-tweezers 62 are brought closer to the mesh 20. In step S202, the nano-tweezers 62 are moved to press the lamella 10 against the film 22. Therefore, the body 10a of the lamella 10 is brought into close contact with the film 22 so that the analysis region 11 faces the film 22.

In step S203, the tip portions of the nano-tweezers 62 are opened to release the lamella 10 from the nano-tweezers 62. Here, the lamella 10 is supported by the film 22. In step S204, the nano-tweezers 62 are moved away from the mesh 20.

As described above, also in Embodiment 4, as in Embodiment 3, since the number of mounting steps can be reduced compared to Embodiments 1 and 2, the transport throughput can be further improved. The analysis system 30 can further improve the throughput of quality evaluation of the wafer. The possibility that the mounting position of the lamella 10 is shifted as the orientation of the lamella 10 is changed can also be prevented.

### Embodiment 5

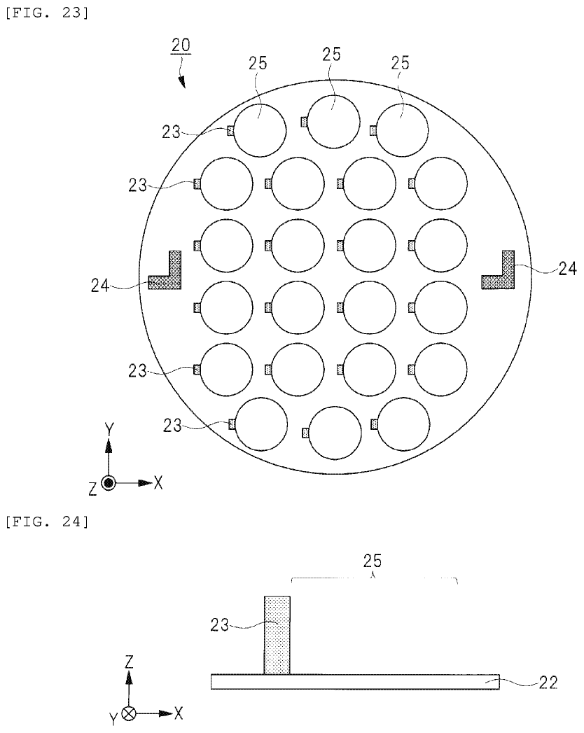

The mesh 20 and a mounting method of the lamella 10 according to Embodiment 5 will be described below with reference to FIGS. 23 to 26. In the following description, differences from Embodiments 1 to 4 will be mainly described, and descriptions of points that overlap with Embodiments 1 to 4 will be omitted. FIGS. 23 and 24 are a plan view and a side view illustrating the mesh 20 according to Embodiment 5.

As illustrated in FIGS. 23 and 24, the mesh 20 according to Embodiment 5 further includes projections 23 and alignment marks 24 provided on the film 22. The material forming the projections 23 may be the same material as the film 22 or may be different from the film 22. The alignment marks are formed by processing a part of the substrate 21. A lamella mounting location 25 is a location where the lamella 10 is scheduled to be brought into close contact with the film 22 while the analysis region 11 is facing with the film 22.

The alignment marks 24 may be provided on the mesh 20 in Embodiments 1 to 4 without being limited to Embodiment 5. Then, a step of performing alignment, which will be described later, may also be performed in Embodiments 1 to 4 without being limited to Embodiment 5.

The lamella 10 used in Embodiment 5 is the L-shaped lamella 10 in FIG. 14. In Embodiment 5, the plurality of mounting methods stored in the host control unit C0 include mounting methods performed in the case of the mesh 20 as illustrated in FIG. 23, which is different from that of Embodiments 1 to 4. Accordingly, the host control unit C0 can designate the mounting method for mounting the L-shaped lamella 10 on the mesh 20 of FIG. 23 to the lamella mounting device 60.

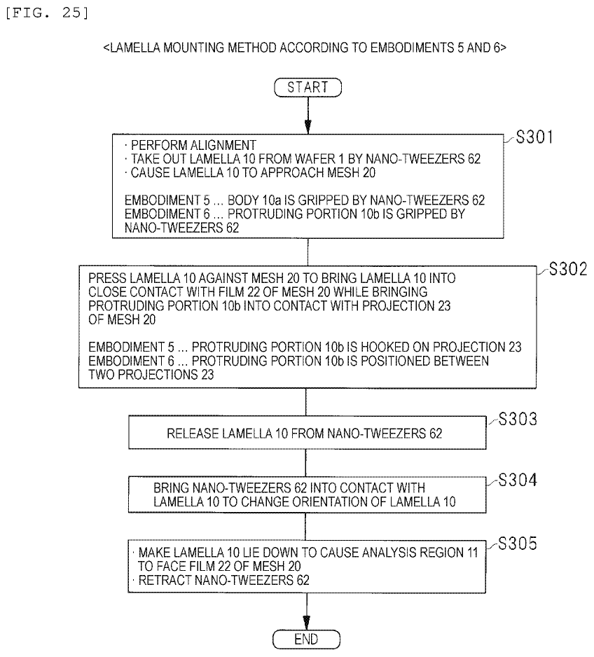

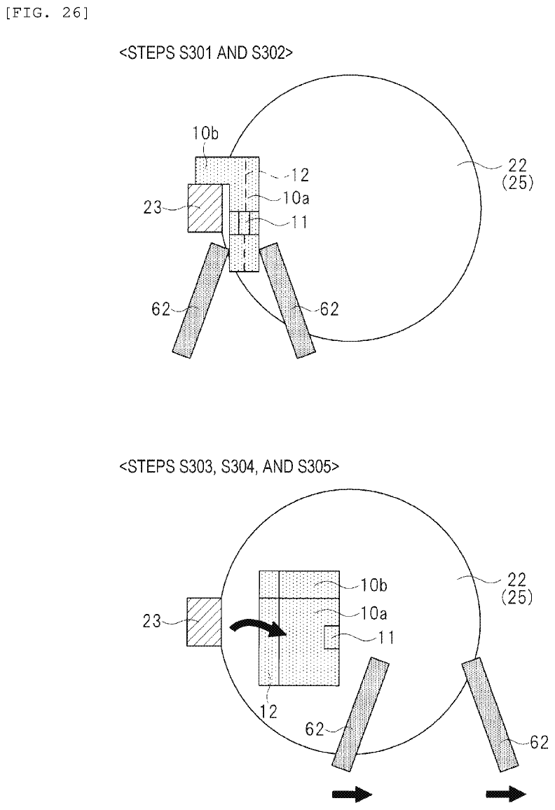

FIG. 25 is a processing flow diagram of a lamella mounting method according to Embodiments 5 and 6. Steps S301 to S305 illustrated in FIG. 26 correspond to steps S301 to S305 in FIG. 25.

In step S301, first, alignment of the mesh 20 is performed. In the alignment step, the alignment marks 24 at both ends of the mesh 20 are used to correct a rotational shift of the mesh 20 by performing an image processing method such as template matching processing.

Next, the nano-tweezers 62 grip the lamella 10 fabricated on a part of the wafer 1 and take out the lamella 10 from the wafer 1. Here, the body 10a is gripped by the nano-tweezers 62 so that the notched region 12 faces the film 22. Next, the nano-tweezers 62 are brought closer to the mesh 20.

Here, the lamella 10 gripped by the nano-tweezers 62 is always mounted at a position where the projection 23 is present. Accordingly, it becomes possible to improve traceability of the mounting position of the lamella 10.

In step S302, the nano-tweezers 62 are moved to press the lamella 10 against the film 22 while the body 10a of the lamella 10 is being gripped by the nano-tweezers 62. Therefore, the lamella 10 is brought into close contact with the film 22. In Embodiment 5, the notched region 12 is brought into close contact with the mesh 20. At this point, the analysis region 11 does not face the film 22.

In step S302, the lamella 10 is brought into close contact with the film 22 by moving the nano-tweezers 62 while hooking the protruding portion n 10b on the projection 23 and bringing the protruding portion 10b into contact with the projection 23. Therefore, since the behavior of the lamella 10 is stable while pressing the lamella 10 against the film 22, the mounting position of the lamella 10 is difficult to shift.

Subsequent steps S303 to S305 are substantially the same as steps S103 to S105 of Embodiment 1. In step S303, the lamella 10 is released from the nano-tweezers 62. Here, the lamella 10 is supported by the film 22, as described above. In step S304, the orientation of the lamella 10 is changed by moving the nano-tweezers 62 and bringing the nano-tweezers 62 into contact with the lamella 10.

In step S305, following step S304, the nano-tweezers 62 are further moved. Therefore, the lamella 10 is laid down, and the lamella 10 becomes horizontal with the film 22. That is, the body 10a of the lamella 10 is brought into close contact with the film 22 so that the analysis region 11 faces the film 22. Here, the mounting position of the lamella 10 is inside the lamella mounting location 25. Next, the nano-tweezers 62 are moved away from the mesh 20.

Then, the lamella 10 mounted on the mesh 20 is analyzed in the lamella analysis device 70. Here, the projection 23 positioned near the lamella 10 can also be used as a mark for fine position adjustment. Therefore, observation accuracy in the lamella analysis device 70 can be improved.

### Embodiment 6

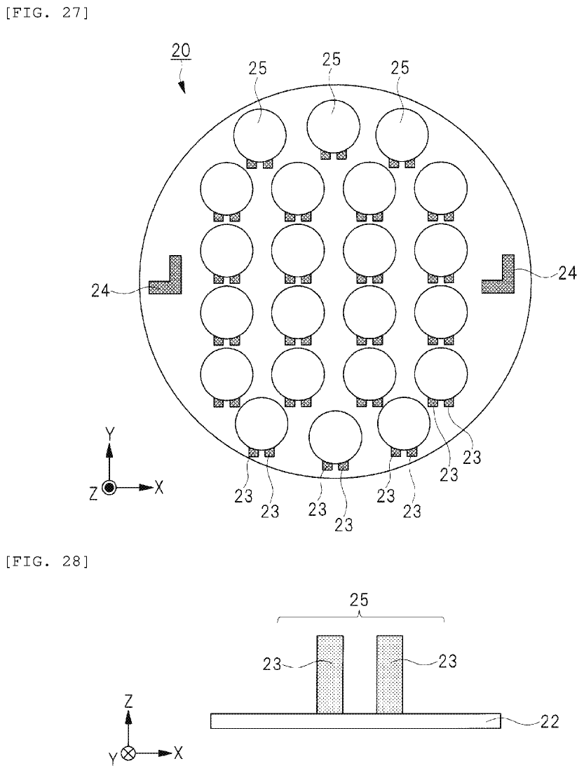

The mesh 20 and a mounting method of the lamella 10 according to Embodiment 5 will be described below with reference to FIGS. 27 to 29. In the following description, differences from Embodiment 5 will be mainly described, and descriptions of points that overlap with Embodiment 5 will be omitted. FIGS. 27 and 28 are a plan view and a side view illustrating the mesh 20 according to Embodiment 5.

As illustrated in FIGS. 27 and 28, the mesh 20 according to Embodiment 6 is substantially the same as in Embodiment 5, but includes two projections 23.

The lamella 10 used in Embodiment 6 is the T-shaped lamella 10 illustrated in FIG. 20. In Embodiment 6, the plurality of mounting methods stored in the host control unit C0 also include mounting methods performed in the case of the mesh 20 as illustrated in FIG. 27 different from that of Embodiments 1 to 5. Accordingly, the host control unit C0 can designate the mounting method for mounting the L-shaped lamella 10 on the mesh 20 of FIG. 27 to the lamella mounting device 60.

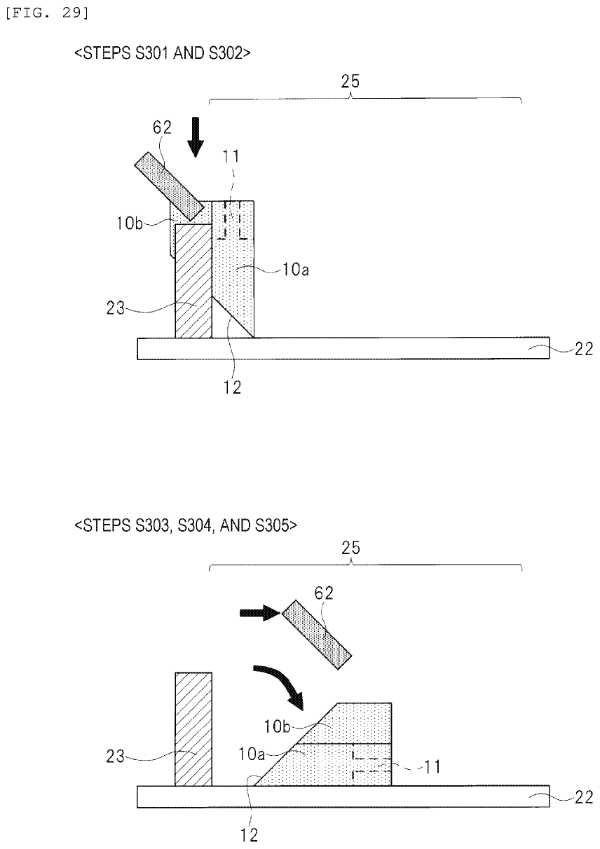

A mounting method of the lamella 10 according to Embodiment 6 will be described below with reference to FIG. 29. As illustrated in FIG. 25, the lamella mounting method according to Embodiment 6 is performed in substantially the same manner as in Embodiment 5 except for some parts. Steps S301 to S305 illustrated in FIG. 29 correspond to steps S301 to S305 in FIG. 25.

In step S301, first, alignment of the mesh 20 is performed as in Embodiment 5. Next, the nano-tweezers 62 grip the lamella 10 fabricated on a part of the wafer 1 and take out the lamella 10 from the wafer 1. Here, the protruding portion 10b is gripped by the nano-tweezers 62 so that the notched region 12 faces the film 22. Next, the nano-tweezers 62 are brought closer to the mesh 20.

Here, the lamella 10 gripped by the nano-tweezers 62 is always mounted at the position where the projections 23 are present. Accordingly, it becomes possible to improve the traceability of the mounting position of the lamella 10.

In step S302, the nano-tweezers 62 are moved to press the lamella 10 against the film 22 while the protruding portion 10b of the lamella 10 is being gripped by the nano-tweezers 62. Therefore, the lamella 10 is brought into close contact with the film 22. In Embodiment 6, the notched region 12 is brought into close contact the mesh 20. At this point, the analysis region 11 does not face the film 22.

In step S302, the lamella 10 is brought into close contact with the film 22 by moving the nano-tweezers 62 while positioning the protruding portion 10b between the two projections 23 and bringing the protruding portion 10b into contact with the projections 23. Here, while pressing the lamella 10 against the film 22, the protruding portion 10b is sandwiched between two projections 23. Therefore, in Embodiment 6, since the behavior of the lamella 10 is more stable than in Embodiment 5, the mounting position of the lamella 10 is more difficult to shift.

Subsequent steps S303 to S305 are substantially the same as steps S303 to S305 of Embodiment 5. In step S303, the lamella 10 is released from the nano-tweezers 62. Here, the lamella 10 is supported by the film 22, as described above. In step S304, the orientation of the lamella 10 is changed by moving the nano-tweezers 62 and bringing the nano-tweezers 62 into contact with the lamella 10.

In step S305, following step S304, the nano-tweezers 62 are further moved. Therefore, the lamella 10 is laid down, and the lamella 10 becomes horizontal with the film 22. That is, the body 10a of the lamella 10 is brought into close contact with the film 22 so that the analysis region 11 faces the film 22. Here, the mounting position of the lamella 10 is inside the lamella mounting location 25. After that, the nano-tweezers 62 are moved away from the mesh 20.

Also in Embodiment 6, in the lamella analysis device 70, the two projections 23 positioned near the lamella 10 can be used as marks for fine position adjustment.

Although the present invention has been specifically described above based on the embodiments described above, the present invention is not limited to the embodiments described above, and various modifications can be made thereto without departing from the scope of the invention.

### REFERENCE SIGNS LIST

1: wafer
1a: connection location
10: lamella
10a: body
10b: protruding portion
11: analysis region
12: notched region
20: mesh (carrier)
21: substrate
22: film
23: projection
24: alignment mark
25: lamella mounting location
30: analysis system
40: lamella fabrication device
41: ion beam column
42: electron beam column
43: sample chamber
44: wafer stage
45: sub-stage
46: charged particle detector
47: X-ray detector
48: probe unit
50: input device
51: display
52: GUI screen
60: lamella mounting device
61: electron beam column
62: nano-tweezers
70: lamella analysis device
71: electron beam column
72: sample stage
73: holder
74: charged particle detector
75: fluorescent plate
76: camera
77: X-ray detector
78: electron source
79: irradiation lens group
80: objective lens
81: projection lens group
82: X-ray detector
83: electron energy loss spectrometer (EELS)
84: EELS detector
85: deflection system
86: annular detector
87: transmission electron detector
88: diaphragm
C0: host control unit
C0a: memory
C0b: processing end determination unit
C0c: processing result evaluation unit
C1: integrated control unit
C2: ion beam column control unit
C3: electron beam column control unit
C4: wafer stage control unit
C5: sub-stage control unit
C6: detector control unit
C7: X-ray detector control unit
C8: probe unit control unit
C9: electron beam column control unit
C10: tweezers control unit
C11: integrated control unit
C12: electron beam column control unit
C13: sample stage control unit
C14: detector control unit
C15: camera control unit
C16: X-ray detector control unit
C17: integrated control unit
CP1, CP2: cross point
EB1, EB2: electron beam
IB: ion beam
OA1 to OA3: optical axis

1-15. (canceled)

16. A lamella mounting method for mounting a lamella to be analyzed using a charged particle beam device on a mesh by tweezers, the method comprising:
(a) a step of gripping the lamella fabricated on a part of a wafer and taking out the lamella from the wafer by the tweezers; and
(b) after the step (a), a step of bringing the lamella into close contact with a first film contained in a mesh by moving the tweezers to press the lamella against the first film while the lamella is being gripped by the tweezers, wherein
the lamella includes a body and an analysis region provided in a part of the body,
a width of the analysis region in a first direction is different from a width of the body in the first direction,
after the step (b), the lamella is in close contact with the first film so that the analysis region faces the first film,
the lamella mounting method is performed using a lamella mounting device that includes the tweezers for gripping the lamella and the mesh for mounting the lamella, and
the lamella mounting device has first information about a shape of the lamella, and is able to execute a mounting method according to the shape of the lamella among a plurality of mounting methods for mounting the lamella to the mesh based on the first information.

17. The lamella mounting method according to claim 16, further comprising:
(c) after the step (b), a step of releasing the lamella from the tweezers; and
(d) after the step (c), a step of changing an orientation of the lamella by moving the tweezers and bringing the tweezers into contact with the lamella, wherein
in the step (b), the analysis region does not face the first film, and
by the step (d), the lamella is brought into close contact with the first film so that the analysis region faces the first film.

18. The lamella mounting method according to claim 17, wherein
the lamella further includes a protruding portion that protrudes from the body in the first direction, and
in the step (b), the protruding portion is brought into close contact with the first film.

19. The lamella mounting method according to claim 17, wherein
the body includes a notched region whose width in the first direction continuously decreases as is far from the analysis region, and
in the step (b), the notched region is brought into close contact with the first film.

20. The lamella mounting method according to claim 17, wherein
the lamella further includes a protruding portion that protrudes from the body in the first direction,
the mesh further includes projections provided on the first film, and
in the step (b), the lamella is brought into close contact with the first film while the protruding portion is brought into contact with the projection.

21. The lamella mounting method according to claim 20, wherein
the mesh includes two of the projections, and
in the step (b), the lamella is brought into close contact with the first film while the protruding portion is positioned between the two projections.

22. The lamella mounting method according to claim 17, wherein
in the step (d), an adhesion force between the first film and the lamella is greater than an adhesion force between the tweezers and the lamella when the tweezers are in contact with the lamella.

23. The lamella mounting method according to claim 16, wherein
the lamella further includes a protruding portion that protrudes from the body in the first direction,
in the step (a), the protruding portion is gripped by the tweezers, and
in the step (b), the body is brought into close contact with the first film so that the analysis region faces the first film while the protruding portion is being gripped by the tweezers.

24. The lamella mounting method according to claim 16, wherein
in the step (b), an adhesion force between the first film and the lamella is greater than an adhesion force between the tweezers and the lamella when the tweezers are gripping the lamella.

25. An analysis system comprising:
a lamella fabrication device that includes an ion beam column;
a lamella mounting device that includes tweezers for gripping a lamella and a mesh for mounting the lamella;
a lamella analysis device that includes an electron beam column including an electron source, a sample stage, and a holder provided on the sample stage; and
a control unit that comprehensively controls the lamella fabrication device, the lamella mounting device, and the lamella analysis device, wherein
the analysis system further comprises
(a) in the lamella fabrication device, a step of fabricating the lamella including a body and an analysis region provided in a part of the body by irradiating a wafer with an ion beam from the ion beam column and etching a part of the wafer,
(b) after the step (a), a step of transporting the wafer on which the lamella is fabricated from the lamella fabrication device to the lamella mounting device,
(c) after the step (b), in the lamella mounting device, a step of gripping the lamella fabricated on a part of the wafer and taking out the lamella from the wafer by the tweezers,
(d) after the step (c), in the lamella mounting device, a step of bringing the lamella into close contact with a first film contained in a mesh by moving the tweezers to press the lamella against the first film while the lamella is being gripped by the tweezers,
(e) after the step (d), a step of transporting the mesh on which the lamella is mounted from the lamella mounting device to the lamella analysis device, and
(f) after the step (e), in the lamella analysis device, a step of analyzing the analysis region by irradiating the analysis region with an electron beam from the electron source while the mesh is being placed on the holder so that the analysis region faces the electron source,
a width of the analysis region in a first direction is different from a width of the body in the first direction,
after the step (d) and before the step (e), the lamella is in close contact with the first film so that the analysis region faces the first film,
the control unit is able to acquire first information about a shape of the lamella from the lamella fabrication device, and
the control unit is able to designate a mounting method according to the shape of the lamella among a plurality of mounting methods for mounting the lamella on the mesh to the lamella mounting device based on the acquired first information.

26. The analysis system according to claim 25, further comprising:
(g) between the (d) step and the (e) step, a step of releasing the lamella from the tweezers; and
(h) between the step (g) and the step (e), a step of changing an orientation of the lamella by moving the tweezers and bringing the tweezers into contact with the lamella, wherein
in the step (d), the analysis region does not face the first film, and
by the step (h), the lamella is brought into close contact with the first film so that the analysis region faces the first film.

27. The analysis system according to claim 26, wherein
the lamella further includes a protruding portion that protrudes from the body in the first direction, and
in the step (d), the protruding portion is brought into close contact with the first film.

28. The analysis system according to claim 26, wherein
the lamella further includes a protruding portion that protrudes from the body in the first direction,
the mesh further includes projections provided on the first film, and
in the step (d), the lamella is brought into close contact with the first film while the protruding portion is brought into contact with the projection.

29. The analysis system according to claim 25, wherein
the lamella further includes a protruding portion that protrudes from the body in the first direction,
in the step (c), the protruding portion is gripped by the tweezers, and
in the step (d), the body is brought into close contact with the first film so that the analysis region faces the first film while the protruding portion is being gripped by the tweezers.
